(19) United States
(12) Patent Application Publication
(10) Pub. No.: US 2011/0116658 A1
(43) Pub. Date: May 19, 2011

(54) FINE NATURAL FIBER AND SPEAKER DIAPHRAGM COATED WITH FINE NATURAL FIBER

(75) Inventors: Kazuyoshi Mimura, Mie (JP); Yukihiro Shimasaki, Hyogo (JP); Hiroshi Shinkoda, Mie (JP); Toshiyuki Koike, Mie (JP)

(73) Assignee: Panasonic Coporation, Osaka (JP)

(21) Appl. No.: 12/674,983

(22) PCT Filed: Sep. 4, 2008
(86) PCT No.: PCT/JP2008/002431

§ 371 Date: Feb. 24, 2010

(30) Foreign Application Priority Data
Oct. 5, 2007 (JP) 2007-261739
Oct. 31, 2007 (JP) 2007-282697

(51) Int. Cl. H03F 99/00; H04R 1/00; H04R 7/02; C08B 15/00; B32B 5/00; D21H 23/24; B02C 23/00

(52) U.S. Cl. 381/120; 381/412; 181/169; 536/56; 428/401; 162/201; 241/25

(57) ABSTRACT

Natural fiber is beaten with a biaxial kneading machine. The beaten natural fiber is processed finely with a bead mill so as to allow the processed natural fiber to have a BET specific surface area not smaller than 1 m²/g. This method provides fine fiber in a short time to form a rigid paper component.

### TECHNICAL FIELD

The present invention relates to fine natural fiber and a method and an apparatus for manufacturing the fiber. The invention also relates to a loudspeaker using the fine natural fiber.

### BACKGROUND ART

As advancing in digital technology recently, electronic devices, such as an audio device and a video device, has made a dramatic improvement in performance. A high-performance loudspeaker suitable for such electronic devices is demanded to have improved performance.

Vibrating components, such as a diaphragm, out of components of the loudspeaker mainly determines sound quality. Therefore, improvements in these components are indispensable to enhance the performance of a loudspeaker. As an aspect of enhancing performance, manufacturers have been making efforts, placing an emphasis on creating sound and characteristics that satisfy the needs of users for each of various applications. To provide sound and characteristics that satisfy their requirements, components, which enable users to have fine adjustments of sound and characteristics of the loudspeaker, made of paper are employed for vibration components.

FIGS. 8A to 8D are a schematic view of a conventional apparatus for manufacturing a paper diaphragm for loudspeaker.

As shown in FIG. 8A, material 10 of the paper diaphragm is put into beater 1 filled with water. Rotary blade 2 rotates to beat material 10 finely in beating section 501A for several days.

Next, as shown in FIG. 8B, beaten material 10A is put into paper-making section 501B and is spread on metal wire mesh 4 and molding die 3 as to remove only water from the material. This process allows material 10A to deposit on mesh 4 and molding die 3 and to be shaped into a diaphragm, thereby providing material 10B.

Next, as shown in FIG. 8C, pressure section 501C heats and presses material 10B of a diaphragm to evaporate water remaining in material 10B.

Next, as shown in FIG. 8D, die 55 of cutting section 501D cuts off an unnecessary outermost periphery and a center hole where a voice coil is inserted from of material 10B, thereby providing diaphragm 502.

As described above, industries of acoustic devices and image display devices have achieved drastic improvements in performance of devices as the advance in digital technology. On the other hand, growing market demands a low-cost loudspeaker used for electronic equipment, such as an acoustic device and an image display device.

Vibrating components of loudspeakers that satisfactorily meet the aforementioned demands are conventionally made of finely processed pulp by a paper-making process. Paper components, particularly a diaphragm is preferably rigid. Processing fiber as fine as possible in advance to the paper-making process provides paper components with rigidity.

It takes a long time to process material 10 as fine as desired by beater 1 of beating section 501A shown in FIG. 8. Besides, blade 2 directly contacts the fibers of material 10, and hence, prevents beaten material 10A from having a long fiber length. This prevents the fibers in material 10A from intertwining insufficiently with each other, hence not providing the vibrating components with a large size and large rigidity.

In a method described in Patent Document 1, material is processed repetitively, according increasing its production cost.

By virtue of the widespread use of digital equipment, a loudspeaker reproduces sound with high quality. Especially, audio industries and car industries that sell cars equipped with an audio device recently demand loudspeakers with excellent sound quality and a small size.

Sound quality largely depends on a diaphragm of a loudspeaker. A paper-made diaphragm is usually used due to advantage that sound quality can be controlled precisely.

A paper diaphragm is conventionally made of kraft pulp of softwood beaten with a beater.

Trend of downsizing devices requires loudspeakers to have an elongate shape, such as a rectangular shape, an oval shape, or an elliptical shape, and accordingly, requires diaphragms to have such an elongate shape. A prior art document discloses a conventional paper diaphragm.

Diaphragms made of paper and having an elongate shape, such as a rectangular shape, an oval shape, or an elliptical shape, extending in a longitudinal direction has both ends along the longitudinal direction are less rigid than other portions of the diaphragm. Loudspeakers including the diaphragm made of paper having the shape are prevented from having high sound quality, high power output, and high reliability.

In order to make up the partial weakness of the shape, a diaphragm is conventionally reinforced with additional components made of paper or film during manufacturing processes. These components are attached entirely or partially to a diaphragm with an adhesive or a tape. However, the additional components entirely attached would increase the weight of the diaphragm, accordingly degrading characteristics of the diaphragm. Similarly, the additional components partially attached increases the number of components of the diaphragm, accordingly preventing the diaphragm from being manufactured efficiently.
Patent Document 1: JP05-211696A

### SUMMARY OF THE INVENTION

Natural fiber is beaten with a biaxial kneading machine. The beaten natural fiber is processed finely with a bead mill so as to allow the processed natural fiber to have a BET specific surface area not smaller than 1 m²/g.

This method provides fine fiber in a short time to form a rigid paper component.

### BRIEF DESCRIPTION OF THE DRAWINGS

FIG. 1A is a schematic view of an apparatus for manufacturing a paper diaphragm for loudspeaker in accordance with Exemplary Embodiment 1 of the present invention.

FIG. 1B is a schematic view of the apparatus in accordance with Embodiment 1.

FIG. 1C is a schematic view of the apparatus in accordance with Embodiment 1.

FIG. 1D is a schematic view of the apparatus in accordance with Embodiment 1.

FIG. 1E is a schematic view of the apparatus in accordance with Embodiment 1.

FIG. 2 is a sectional view of the diaphragm in accordance with Embodiment 1.

FIG. 3 is a flow chart for showing a method for manufacturing a diaphragm for loudspeaker in accordance with Exemplary Embodiment 2 of the invention.

FIG. 4 is a plan view of a loudspeaker in accordance with Embodiment 2.

FIG. 5 is a sectional view of the loudspeaker at line 5-5 shown in FIG. 4.

FIG. 6 is an external view of a device in accordance with Embodiment 2.

FIG. 7 is a sectional view of another device in accordance with Embodiment 2.

FIG. 8A is a schematic view of a conventional apparatus for manufacturing a paper diaphragm for loudspeaker.

FIG. 8B is a schematic view of the conventional apparatus for manufacturing the paper diaphragm for loudspeaker.

FIG. 8C is a schematic view of the conventional apparatus for manufacturing the paper diaphragm for loudspeaker.

FIG. 8D is a schematic view of the conventional apparatus for manufacturing the paper diaphragm for a loudspeaker.

### REFERENCE NUMERALS

20 Biaxial Kneading Machine
21 Bead Mill
24 Magnetic Circuit
25 Magnetic Gap
26 Frame
27A Diaphragm Body
27 Diaphragm
28 Voice Coil
41 Enclosure
42 Amplifier
120 Supporter

### DETAILED DESCRIPTION OF PREFERRED EMBODIMENTS

### Exemplary Embodiment 1

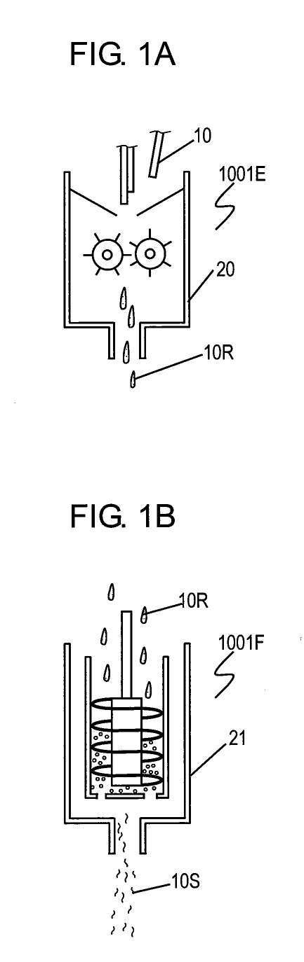

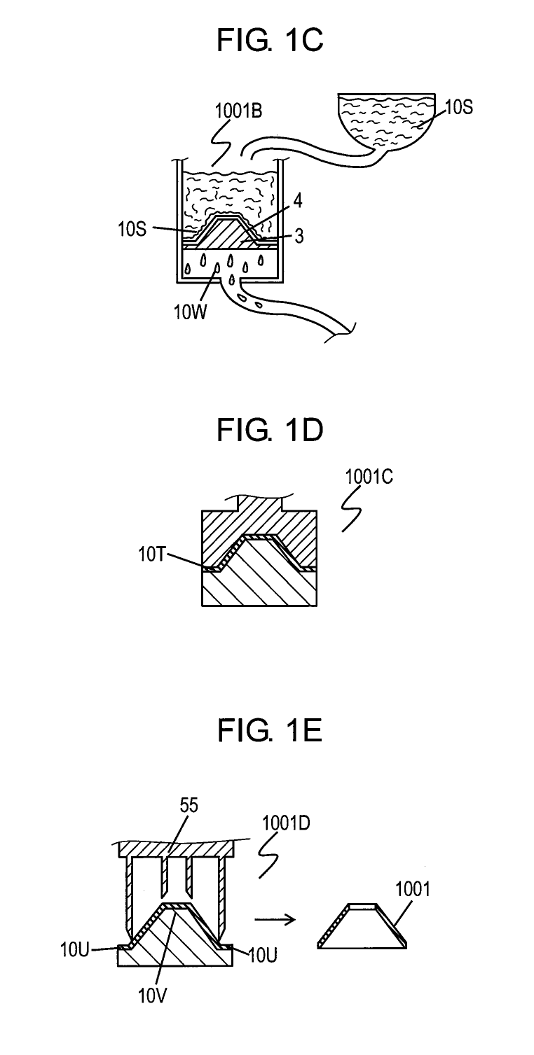

FIGS. 1A to 1E are schematic views of an apparatus for manufacturing loudspeaker component 1001 in accordance with Exemplary Embodiment 1 of the present invention. FIG. 2 is a sectional view of loudspeaker component 1001. Loudspeaker component 1001 is a paper diaphragm for loudspeaker.

FIG. 1A illustrates beating section 1001E. Beating section 1001E includes pressure kneader 20 as a biaxial kneading machine. Material 10 of loudspeaker component 1001 is put into pressure kneader 20 and finely beaten to obtain material 10R. Material 10 is natural fiber, bamboo fiber according to Embodiment 1. Material 10R has a fiber length which the natural fiber has at cells. Material 10R obtained by pressure kneader 20 provides fibers intertwined with each other more closely after the paper-making process than material cut finely with a cutter, such as a cutting mill, hence providing a paper component with high rigidity.

FIG. 1B illustrates milling section 1001F including bead mill 21. Material 10R processed in the beating process is put into bead mill 21 so as to be finely processed by collision with beads, thereby providing material 10S. Bead mill 21 finely processes the material while avoiding reducing the fiber length and provides natural fiber with a BET specific surface area of 1 m²/g. Natural fiber having a BET specific surface area greater than 5 m²/g prevents not only water but also the fiber from passing through metal wire mesh 4 in the paper-making process, hence not providing a diaphragm with rigidity required for diaphragm.

FIG. 1C illustrates paper-making section 1001B. Material 10S processed finely is supplied to paper-making section 1001B and deposited on molding die 3 and metal wire mesh 4 placed on die 3. At that time, water 10W of material 10S is drained through die 3 and mesh 4. Then, accumulated material 10S is formed into a shape of a diaphragm for a loudspeaker.

FIG. 1D illustrates pressurizing section 1001C. Deposited material 10S is heated and pressurized as to evaporate water remaining in material 10S, thereby providing molded product 10T is thus obtained.

FIG. 1E illustrates cutting section 1001D. Molding die 55 cuts molded product 10T to cut off center hole 10V in which a voice coil is inserted and unnecessary outermost periphery 10U. This cutting process provides loudspeaker component 1001, the paper diaphragm for loudspeaker shown in FIG. 2.

According to Embodiment 1, material 10S deposited in paper-making section 1001B is heated and pressurized in pressurizing section 1001C so as to obtain molded product 10T. However, it is not limited to above. Molded product 10T may be formed as a non-press diaphragm without the applying of heat and pressure in pressurizing section 1001C. In this case, deposited material 10S is dried for one or two days.

Loudspeaker component 1001 is the diaphragm, but can be a dust cap or a sub-cone made of paper.

Although the natural fiber used for material 10 according to Embodiment 1 is bamboo fiber, but is not limited to it. A pulp sheet manufactured by paper manufacturers can be beaten for a long time acceptably sufficiently even with an ordinary beater instead of the biaxial kneading machine of pressure kneader 20. Natural fiber, such as bamboo fiber, having a branched shape, can be beaten sufficiently with pressure kneader 20.

Pressure kneader 20 can beat natural fiber regardless of the shape of the fiber. Specifically, pressure kneader 20 increases friction between fibers without mixing, and makes the surface of fiber fuzzy without cutting, providing the natural fiber with a feathery shape.

After beaten with pressure kneader 20 as a biaxial kneading machine, the fiber is supplied into bead mill 21 and further finely processed, with strong shearing force, into a feathery shape. Bead mill 21 generates friction between the beads and fibers or between fibers, allowing material 10R to have feathery shaped fiber without decreasing the fiber length.

The shape of the fiber can be controlled by the types or the amounts of beads used in bead mill 21. In the case that material 10 is natural fiber containing much cellulose, inexpensive glass beads shape the material into fine fiber with a BET specific surface area not smaller than 1 m²/g.

The average fiber length of finely processed material 10S is preferably not smaller than 0.5 mm, and more preferably not smaller than 0.7 mm. The fibers processed to have such length are sufficiently intertwined with each other in the paper-making process. However, fiber having excessively long fiber length, e.g. an average length greater than 3 mm, may clog in gaps in the bead mill.

Material 10 is not limited to a specific material out of natural fiber, however, bamboo fiber is suitable for material 10S since the bamboo fiber has the surface with a four-layered structure having the feathery shape efficiently due to friction between fiber.

Material 10S, natural fiber, manufactured by the method shown in FIGS. 1A to 1E, provides a rigid and light paper component as loudspeaker component 1001, such as a diaphragm for loudspeaker, a sub-cone for loudspeaker, and a dust cap for loudspeaker. The diaphragm out of these loudspeaker components is required to have a high rigidity and a small weight, hence being implemented by loudspeaker component 1001.

The usage of the natural fiber as finely processed material 10S is not limited to the above applications. For example, the fine natural fiber may be mixed with other natural cellulose to provide a paper component of a loudspeaker. The fine natural fiber may be applied onto the surface of a paper component by dipping, spraying, or suction depositing.

Then, examples of loudspeaker component 1001 according to Embodiment 1 will be described below, however, do not limit the present invention.

### Example 1

500 g of Material 10 made of bamboo fiber having a length of about 10 cm was put into pressure kneader 20 having a capacity of 3 litters and beaten for 20 minutes at a rotation speed of 25 rpm, thereby providing material 10R. Beaten material 10R had an average fiber length of 2.5 mm and had a Canadian Standard Freeness of 750 ml.

Material 10R was mixed with water so as to prepare about 3% of aqueous dispersion. The aqueous dispersion was put into bead mill 21 with a capacity of 3 litters and finely processed with glass beads of 100 g for 20 minutes, thereby providing material 10S. Such finely processed material 10S had an average fiber length of 1 mm and a BET specific surface area of 2.22 m²/g. The Canadian Standard Freeness of material 10S was not measurable.

### Comparative Example 1

Material 10R of example 1 produced with pressure kneader 20 was mixed with water so as to prepare 1% of aqueous dispersion. The aqueous dispersion was put into a pressure homogenizer. However, the fiber of material 10S clogged in a small orifice bore of the pressure homogenizer, and thus, was not processed.

### Comparative Example 2

Bamboo fiber with a length of about 10 cm was cut to have a length of about 0.5 mm, and then, mixed with water so as to 1% of prepare aqueous dispersion. The aqueous dispersion was finely processed with a pressure homogenizer for five times at a pressure of 50 MPa, thereby providing fine fiber of the material of Comparative Example 2. The fiber of Comparative Example 2 had an average fiber length of 0.42 mm, a Canadian Standard Freeness of 80 ml, and a BET specific surface area of 0.95 m²/g.

### Comparative Example 3

Bamboo fiber with a length of about 10 cm was cut to have a length of about 0.5 mm, and then, mixed with water so as to 1% of prepare aqueous dispersion. Similarly to Example 1, the aqueous dispersion was put into bead mill 21 to finely process the bamboo fiber, thereby providing material fiber of Comparative Example 3. The fiber of Comparative Example 3 had an average fiber length of 0.34 mm and a BET specific surface area of 2.1 m²/g. The Canadian Standard Freeness of Example 3 was not measurable.

### Example 2

Material 10R of Example 1 produced with pressure kneader 20 was mixed with material 10S produced with bead mill 21 to form loudspeaker component 1001. To be specific, 90 wt % of material 10R was mixed with 10 wt % of material 10S to form a flat plate and a loudspeaker diaphragm with a diameter of 16 cm. The acoustic velocity of the flat plate ranged from 3500 m/s to 4000 m/s.

### Comparative Example 4

A flat plate and a loudspeaker diaphragm with a diameter of 16 cm were produced with only material 10R of Example 1 produced with pressure kneader 20. The acoustic velocity of the flat plate ranged from 3000 m/s to 3200 m/s.

### Comparative Example 5

A flat plate and a loudspeaker diaphragm with a diameter of 16 cm were produced with 700 ml of wood pulp beaten with a beater. The acoustic velocity of the flat plate ranged from 2300 m/s to 2500 m/s.

### Example 3

Similarly to Comparative Example 4, a flat plate and a loudspeaker diaphragm with a diameter of 16 cm were produced with only material 10R of Example 1 produced with pressure kneader 20. Then, material 10S produced with bead mill 21 was sprayed on the flat plate and the loudspeaker diaphragm. After being dried, sprayed material 10S had a weight of about 0.3 g. The acoustic velocity of the flat plate ranged from 3800 m/s to 4500 m/s.

Loudspeakers including diaphragms of Examples 2 and 3 and Comparative examples 4 and 5 were assembled. Five inspectors evaluated the loudspeakers in items: A) clearness of sound; B) energy of sound; and C) mellowness of sound. Each inspector provided each evaluated item with three points, and thus, provided nine points total, hence providing 45 points as a full score. The diaphragm of Example 2 scored 39 points. The diaphragm of Example 3 scored 41 points. The diaphragm of Comparative Example 4 scored 30 points. The diaphragm of Comparative Example 5 scored 21 points. Thus, loudspeaker paper component 1001 made of the fine fiber of material 10S has a high sound pressure and high sound quality having a wide reproducing range.

Besides, the method according to Embodiment 1 can be easily scaled up, providing loudspeaker paper component 1001 with low cost, thus contributing to low-cost loudspeakers.

### Exemplary Embodiment 2

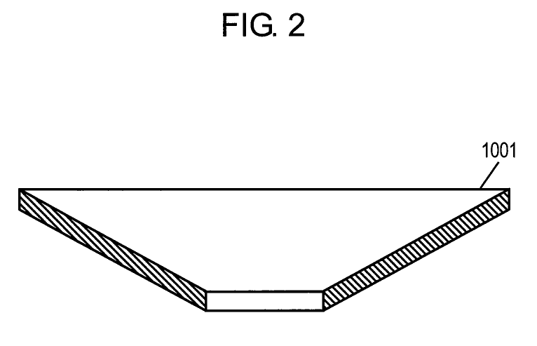

FIG. 3 is a flow chart showing a method for manufacturing a diaphragm for loudspeaker in accordance with Exemplary Embodiment 2 of the present invention. Similarly to the method of manufacturing loudspeaker component 1001 shown in FIGS. 1A through 1E in Embodiment 1, material of a loudspeaker diaphragm is put into water in a beater, and finely beaten for several days (step S101).

Next, the beaten material deposits on a molding die and a metal wire mesh on the die in a paper-making process. In this process, only water in the material is sucked with a suction force to cause the material depositing is formed into a shape of a loudspeaker diaphragm (step S102).

Dispersion solution is prepared by diluting fine natural fiber having an average fiber length not smaller than 0.5 mm and a BET specific surface area not smaller than of 1 m²/g with solvent, such as water. After that, the dispersion solution is sprayed on a part of a diaphragm body other than a masked part of the diaphragm body so as not to be sprayed (step S103). At this moment, since the diaphragm body is sucked on the die, only water contained in the natural-fiber solution sprayed on the diaphragm body is removed.

Next, the diaphragm is heated and pressurized to cause water remaining in the diaphragm to evaporate (step S104).

After that, an outermost periphery of the diaphragm which is unnecessary as the diaphragm and a center section in which a voice coil is inserted are cut out with a molding die (step S105), thereby providing the loudspeaker diaphragm according to Embodiment 2.

The above method is applicable to a method for manufacturing a loudspeaker diaphragm containing a paper-making process.

The spaying process at step S103 is not necessarily executed simultaneously to or after the paper-making process at step S102. That is, the spraying process can be executed after the pressurizing process at step S104 or after the cutting process at step S105.

According to Embodiment 2, after beaten with the biaxial kneading machine, the natural fiber is further finely processed by a bead mill. The method according to this embodiment processes the material more finely in a shorter time more inexpensively than a general processing method with a beater. That is, the method according to this embodiment manufactures the fiber exhibiting a great reinforcing effect on a surface of the diaphragm efficiently.

The fine natural fiber preferably has an average fiber length not less than 0.7 mm and not more than 1.5 mm in view of the rigidity of the surface and of effectively producing fine fiber. The natural fiber preferably has a BET specific surface area not smaller than 1 m²/g in view of improvement in rigidity.

The natural fiber to be applied is preferably bamboo fiber. The bamboo fiber itself has high rigidity. In addition, the bamboo fiber has a surface of four-layered structure which can easily change into a feathery surface with friction.

A method for manufacturing fine bamboo fiber and a diaphragm having the bamboo fiber sprayed thereon in accordance with Embodiment 2 will be described below.

700 g of material of bamboo fiber with an average fiber length of about 10 cm was put into a pressure kneader with a capacity of 3 litters and beaten at a rotation speed of 25 rpm for 20 min. The beaten material was dispersed into water so as to prepare 5% of aqueous dispersion. The aqueous dispersion was put into a bead mill with a capacity of 3 litters and beaten with glass beads in the mill for 20 minutes. The beaten material had an average fiber length of 0.8 mm and a BET specific surface area of 2.11 m²/g. The aqueous dispersion containing the beaten material was diluted with water, thereby providing dispersion solution containing 2% of bamboo fiber.

In order to reinforce a diaphragm body partially, the dispersion solution was sprayed on the diaphragm body tightly fitting onto a paper-making molding die. A part of the diaphragm body which is not to be sprayed was masked. The dispersion solution was sprayed on two parts of the diaphragm body adjacent to flat portions at both ends of the diaphragm body in a longitudinal direction. After that, the diaphragm body was dried for 5 minutes at a temperature of 160° C., thereby providing a diaphragm.

The diaphragm gained a weight by 0.5 g that corresponds to the fine bamboo fiber sprayed thereon. This additional weight does not affect characteristics of the diaphragm. A diaphragm having a shape, such as a rectangular shape, an oval shape, or an elliptical shape, elongated in a longitudinal direction has less rigid portions adjacent to flat portions at both ends in the longitudinal direction than other portions of the diaphragm. The fine natural fiber, especially bamboo fiber, sprayed on the less rigid portions increases rigidity of the diaphragm without adverse effects caused by the weight of the sprayed fiber and without degrading workability. In this method, natural fiber is beaten with the biaxial kneading machine, and then further beaten by a bead mill so as to be finely processed fiber, thereby manufacturing the fine natural fiber inexpensively in a short time.

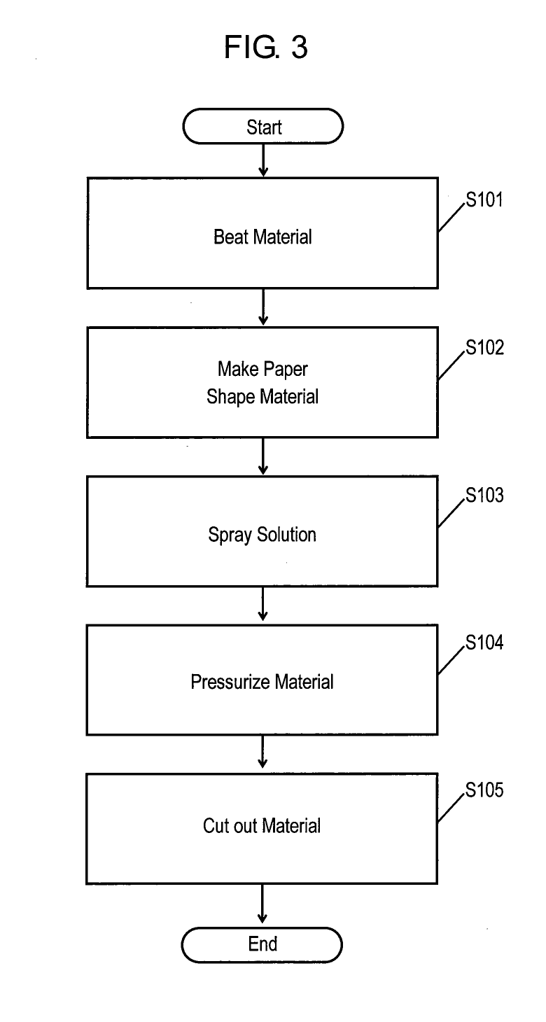

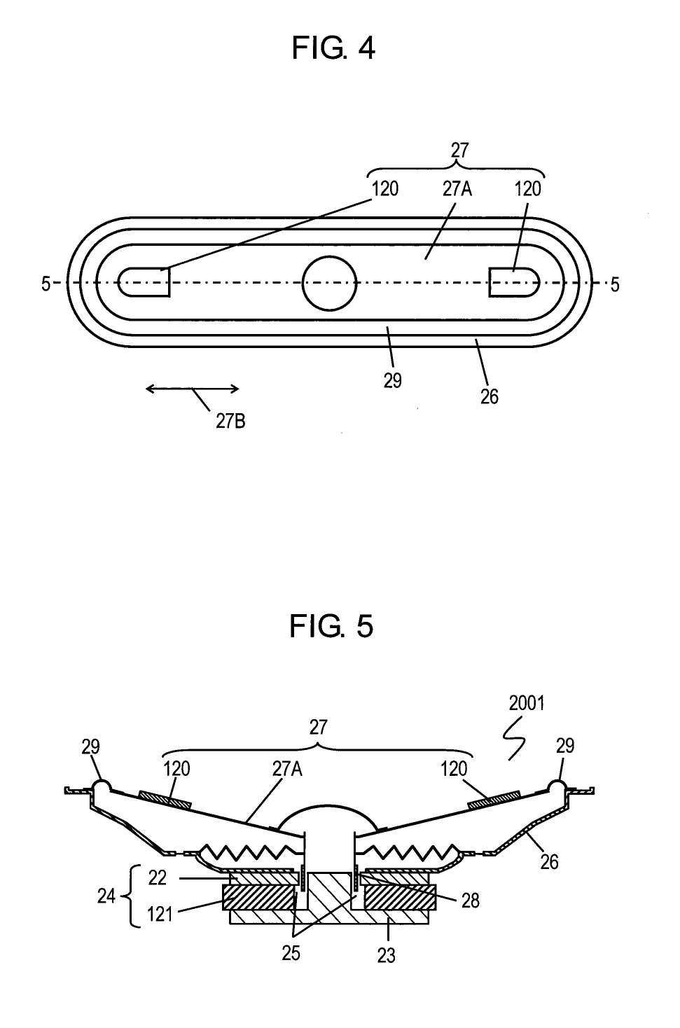

FIG. 4 is a plan view of loudspeaker 2001 in accordance with Embodiment 2. FIG. 5 is a sectional view of loudspeaker 2001 on line 5-5 shown in FIG. 4. Loudspeaker 2001 includes frame 26, diaphragm body 27A, and supporter 120 provided on diaphragm body 27A. Frame 26 has a shape contributing to the reducing of the size of a video-audio integrated system. Diaphragm 27 includes diaphragm body 27A and supporter 120. Diaphragm body 27A has an oval shape that extends in longitudinal direction 27B. Instead of the oval shape, diaphragm body 27A can have a rectangular or an elliptical shape extending in longitudinal direction 27B. Supporter 120 is formed by spraying the above dispersion solution containing bamboo fiber on diaphragm body 27A for partially reinforcing diaphragm body 27A. Supporter 120 is provided on diaphragm body 27A by applying the dispersion solution partially to both ends in longitudinal direction 27B of the diaphragm body.

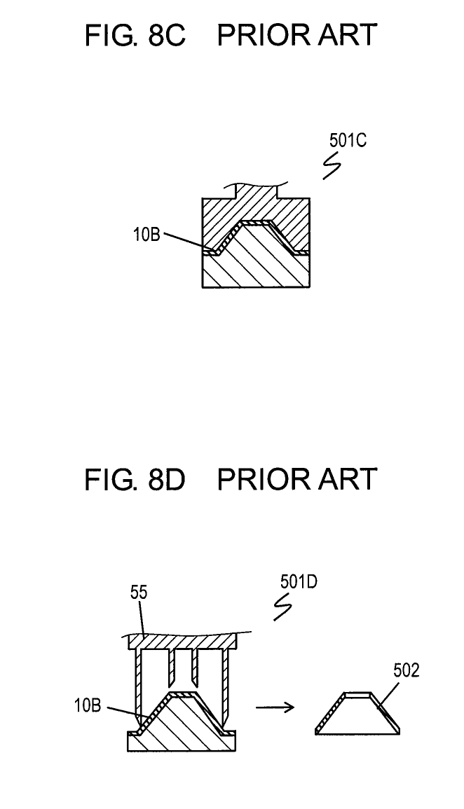

Supporter 120 increases the rigidity of loudspeaker diaphragm 27, and suppresses resonance caused by poor rigidity of a diaphragm. As a result, the loudspeaker reliably provides powerful output with crisp deep bass sound to resonance-reduced clear high tones. Diaphragm body 27A may be component 1001 shown in FIG. 1E according to Embodiment 1 or may be conventional diaphragm 502 shown in FIG. 8D. Further, diaphragm body 27A may be made of material 10R shown in FIG. 1A.

As shown in FIG. 5, magnet 121 is held between upper plate 22 and yoke 23, constituting closed-type magnetic circuit 24. Frame 26 is coupled to upper plate 22 of magnetic circuit 24. The outer periphery of diaphragm 27 is connected to the periphery of frame 26 via edge 29. One end of voice coil 28 is connected to the center of diaphragm 27, and the other end of voice coil 28 is placed in magnetic gap 25 of magnetic circuit 24.

Loudspeaker 2001 includes closed-type magnetic circuit 24, but may include an open-type magnetic circuit instead.

Diaphragm 27 may be integrated unitarily with edge 29.

Loudspeaker 2001 including supporter 120 formed by applying the solution containing the fine bamboo fiber and a comparative example of loudspeaker including a diaphragm formed of only diaphragm body 27A without supporter 120 were prepared and measured in frequency-sound pressure characteristics. The loudspeaker of the comparative example had a deviation of sound pressure of 12 dB, while loudspeaker 2001 had a deviation of 5 dB. Thus, loudspeaker 2001 has 7 dB-improvement in deviation of sound pressure for a small increase of weight by 0.5 g.

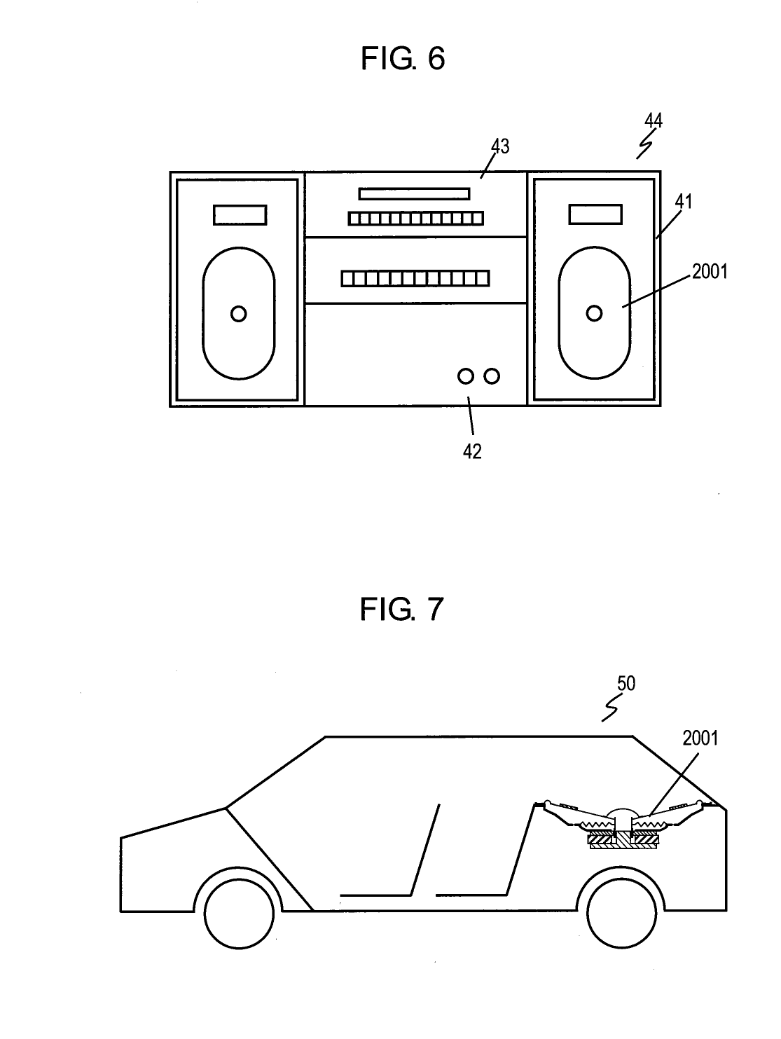

FIG. 6 is schematic view of device 44 in accordance with Embodiment 2. Device 44 is a mini component stereo system. Loudspeaker 2001 is accommodated in housing (enclosure) 41, constituting a loudspeaker system. Device 44 includes amplifier 42 for generating a signal input to loudspeaker 2001 and player 43 for outputting a source to be supplied to amplifier 42.

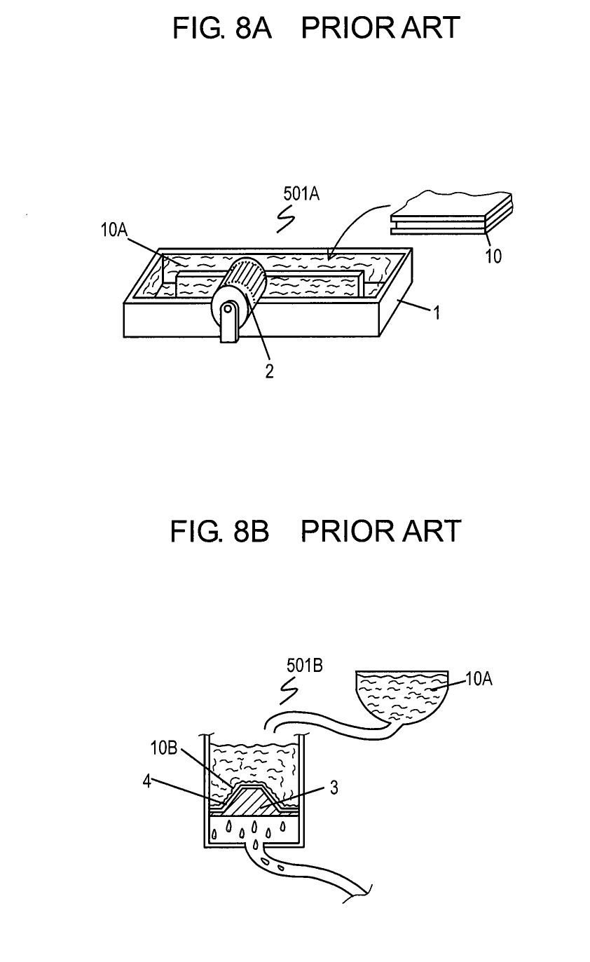

FIG. 7 is a sectional view of another device 50 in accordance with Embodiment 2. Device 50 is a vehicle. Loudspeaker 2001 accommodated in a housing, such as a rear tray or a front panel, is used as a component of a car navigation system or a car audio system.

### INDUSTRIAL APPLICABILITY

A method according to the present invention provides fiber providing a rigid paper component manufactured in a short time. The method provides a diaphragm with high quality.

1. A method for manufacturing fine natural fiber, comprising:
beating natural fiber with a biaxial kneading machine; and
processing finely the beaten natural fiber with a bead mill so as to allow the processed natural fiber to have a BET specific surface area not smaller than 1 m²/g.

2. The method according to claim 1, wherein said processing finely the beaten natural fiber comprises processing finely the beaten natural fiber with the bead mill so as to allow the processed natural fiber to have an average fiber length not smaller than of 0.5 mm.

3. A fine natural fiber manufactured by the method according to claim 1.

4. The fine natural fiber according to claim 3, wherein the fine natural fiber has an average fiber length not smaller than 0.5 mm.

5. The fine natural fiber according to claim 3, wherein the natural fiber is bamboo fiber.

6. A loudspeaker component comprising the fine natural fiber according to claim 3.

7. The loudspeaker component according to claim 6, wherein the loudspeaker component contains the fine natural fiber not less than 3 wt % and not more than 20 wt %.

8. The loudspeaker component according to claim 6, wherein the loudspeaker component is a diaphragm.

9. The loudspeaker component according to claim 6, comprising:
a diaphragm body; and
a supporter provided on the diaphragm body, the supporter being made of the fine natural fiber.

10. The loudspeaker component according to claim 9, wherein the loudspeaker component contains the fine natural fiber not less than 3 wt % and not more than 20 wt %.

11. An apparatus for manufacturing fine natural fiber, comprising:
a biaxial kneading machine for beating natural fiber; and
a bead mill for finely processing the beaten natural fiber.

12. A method for manufacturing a diaphragm for loudspeaker, comprising:
providing a diaphragm body manufactured by a paper-making method, the diaphragm extending in a longitudinal direction; and
applying fine natural fiber partially onto both ends of the diaphragm body in the longitudinal direction.

13. The method according to claim 12, further comprising:
beating natural fiber with a biaxial kneading machine; and
processing finely the beaten natural fiber with a bead mill,
wherein said applying the fine natural fiber partially onto the both ends of the diaphragm body in the lengthwise direction comprises spraying the fine natural fiber partially onto the both ends of the diaphragm body in the lengthwise direction.

14. The method according to claim 13, wherein said preparing the diaphragm body comprises producing the diaphragm body by a paper-making method with the natural fiber processed finely.

15. The method according to claim 13, wherein the natural fiber comprises bamboo fiber.

16. The method according to claim 12, wherein the fine natural fiber comprises bamboo fiber.

17. The method according to claim 12, wherein said applying the fine natural fiber partially onto the both ends of the diaphragm body in the lengthwise direction comprises spraying the fine natural fiber partially onto the both ends of the diaphragm body in the lengthwise direction.

18. The method according to claim 12, wherein the diaphragm body has a rectangular shape, an oval shape, or an elliptical shape.

19. A diaphragm for loudspeaker, comprising:
a diaphragm body made of paper and extending in a longitudinal direction; and
a fine natural fiber applied partially onto both ends in the longitudinal direction of the diaphragm body.

20. A loudspeaker comprising:
the diaphragm according to claim 19;
a magnetic circuit having a magnetic gap;
a frame attached to an outer periphery of the diaphragm; and
a voice coil connected to the diaphragm, the voice coil having a portion placed in the magnetic gap of the magnetic circuit.

21. A device comprising:
the loudspeaker according to claim 20; and
an amplifier for generating a signal input to the loudspeaker.

22. A device comprising;
the loudspeaker according to claim 20; and
a housing for accommodating the loudspeaker.

23. A loudspeaker component comprising the fine natural fiber according to claim 4.

24. A loudspeaker component comprising the fine natural fiber according to claim 5.
